(19) United States
(12) Patent Application Publication
(10) Pub. No.: US 2025/0140622 A1
(43) Pub. Date: May 1, 2025

(54) METHOD OF FIXING PROTECTIVE MEMBER

(71) Applicant: DISCO CORPORATION, Tokyo (JP)

(72) Inventors: Noboru TAKEDA, Tokyo (JP); Norihisa ARIFUKU, Tokyo (JP)

(21) Appl. No.: 18/904,320

(22) Filed: Oct. 2, 2024

(30) Foreign Application Priority Data
Oct. 26, 2023 (JP) 2023-183666

(51) Int. Cl. H01L 23/31; H01L 21/56; H01L 21/683; H01L 23/29

(52) U.S. Cl. CPC H01L 23/3121; H01L 21/561; H01L 21/6835; H01L 23/293

(57) ABSTRACT

A method of fixing a water-soluble protective member to a target includes a contacting step of bringing the target and the protective member into contact with each other, and after the contacting step, an affixing step of affixing the protective member to the target by supplying water to the protective member.

### BACKGROUND OF THE INVENTION

### Field of the Invention

The present invention relates to a method of fixing a protective member to a target.

### Description of the Related Art

Device chip fabrication processes use wafers each having devices constructed in respective areas demarcated by a grid of streets or projected dicing lines established on the wafer. The wafers are divided along the streets into device chips that include the respective devices. The device chips thus fabricated will be incorporated in various electronic appliances such as cellular phones and personal computers, for example.

For dividing a wafer, a cutting apparatus may be used to cut through the wafer with an annular cutting blade. In addition, development of laser beam processing that divides a wafer with a laser beam has been under way in recent years. For example, a laser beam is applied to a wafer to form grooves by way of ablation in the wafer along the streets for dividing the wafer (see JP H10-305420A). The laser beam processing provides an increased processing efficiency because it operates at a higher processing rate than the cutting blade used to cut through wafers. The laser beam processing has an additional merit in that it is applicable to hard wafers that are difficult to cut through with the cutting blade.

When a laser beam is applied to a wafer, the wafer produces swarf such as melted mass or debris in its region irradiated with the laser beam. If the swarf is attached to the wafer or devices thereon, then the wafer or the devices are contaminated, tending to lower quality of the devices. To avoid a drawback, it has been customary to form a protective film on a wafer before the wafer is processed by a laser beam. For example, JP 2004-188475A discloses a method of processing a wafer with a laser beam by forming a protecting film on the wafer by way of spin coating and thereafter applying the laser beam to the wafer through the protective film. The protective film that covers the wafer is effective to prevent swarf from being attached to the wafer and devices thereon at the time the wafer is processed by the laser beam.

### SUMMARY OF THE INVENTION

A face side of a target such as a wafer to be processed by a laser beam may not necessarily be flat and may have surface irregularities. For example, providing bumps, i.e., protrusive electrodes, are connected to devices on the face side of the target, the target provides different heights in regions where the bumps exists and in regions where the bumps do not exist, resulting in bump-induced surface irregularities on the face side of the target.

When the face side of a target having surface irregularities is coated with a protective film by spin coating, the protective film formed on the target has an essentially even upper surface. As a result, the protective film has different thicknesses in regions where it covers protruding portions of the target and in regions where it covers recessed portions of the target, so that the protective film itself has thickness irregularities. Therefore, the regions where the protective film covers the protruding portions of the target are relatively thin, resulting in a lack of enough protection of the target in those regions. One solution would be to make a protective film setting such that the recessed portions of the target are to be covered with a sufficiently thick protective film. However, such a protective film setting would require an increased period of time for forming the protective film and hence make productivity lower. In addition, the regions where the protective film covers the protruding portions of the target would become excessively thick and tend to prevent the target from being smoothly processed subsequently.

The present invention has been made in view of the above difficulties. It is an object of the present invention to provide a method of fixing a protective member for protecting a target in a manner to reduce thickness variations of the protective member.

In accordance with an aspect of the present invention, there is provided a method of fixing a water-soluble protective member to a target. The method includes a contacting step of bringing the target and the protective member into contact with each other, and after the contacting step, an affixing step of affixing the protective member to the target by supplying water to the protective member.

In accordance with another aspect of the present invention, there is provided a method of fixing a water-soluble protective member to a target. The method includes a water supplying step of supplying water to the target, and after the water supplying step, an affixing step of affixing the protective member to the target by bringing a surface of the target to which the water has been applied and the protective member into contact with each other.

In accordance with a further aspect of the present invention, there is provided a method of fixing a water-soluble protective member to a target. The method includes a water supplying step of supplying water to the protective member, and after the water supplying step, an affixing step of affixing the protective member to the target by bringing the target and the protective member into contact with each other.

Preferably, the water is supplied as a mist of water to the target or the protective member. Preferably, the protective member is affixed to the target while the protective member is being heated. Preferably, the target and the protective member are brought into contact with each other in a decompressed environment.

According to the aspects of the present invention, for fixing the protective member to the target, the supplied water contacts the water-soluble protective member, dissolving part of the protective member. The protective member can thus be affixed to the target along surface irregularities thereof, and thickness variations of the protective member due to the surface irregularities of the target are reduced.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1A is a perspective view of a target;

FIG. 1B is an enlarged fragmentary front elevational view of the target;

FIG. 2 is a flowchart of a method of fixing a protective member according to a first embodiment of the present invention;

FIG. 3A is a front elevational view, partly in cross section, of the target and the protective member in a contacting step of the method according to the first embodiment;

FIG. 3B is an enlarged fragmentary front elevational view, partly in cross section, of the target and the protective member after the contacting step of the method according to the first embodiment;

FIG. 4A is a front elevational view, partly in cross section, of the target and the protective member in an affixing step of the method according to the first embodiment;

FIG. 4B is an enlarged fragmentary front elevational view, partly in cross section, of the target and the protective member after the affixing step of the method according to the first embodiment;

FIG. 5 is a perspective view of the target with the protective member fixed thereto;

FIG. 6 is a front elevational view, partly in cross section, of a laser processing apparatus;

FIG. 7 is a front elevational view, partly in cross section, of a cleaning apparatus;

FIG. 8 is a flowchart of a method of fixing a protective member according to a second embodiment of the present invention;

FIG. 9 is a front elevational view, partly in cross section, of the target in a water supplying step of the method according to the second embodiment;

FIG. 10A is a front elevational view, partly in cross section, of the target and the protective member in an affixing step of the method according to the second embodiment; and

FIG. 10B is an enlarged fragmentary front elevational view, partly in cross section, of the target and the protective member after the affixing step of the method according to the second embodiment.

### DETAILED DESCRIPTION OF THE PREFERRED EMBODIMENTS

### First Embodiment

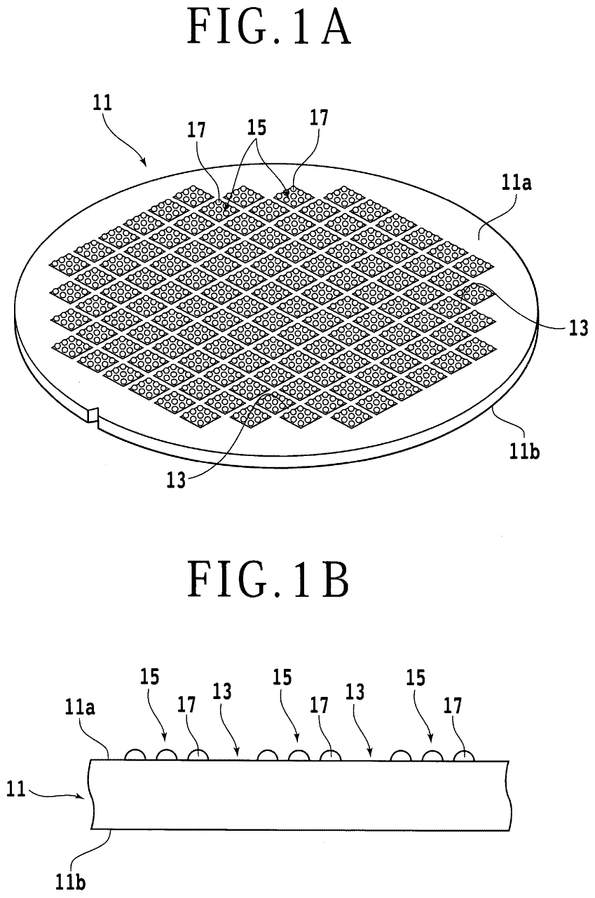

A method of fixing a protective member according to a first embodiment of the present invention will be described below with reference to the accompanying drawings. First, a structural example of a target to which a protective member can be fixed by the method will be described below. FIG. 1A illustrates in the target, denoted by 11, in perspective, and FIG. 1B illustrates the target 11 in enlarged fragmentary front elevation.

After a protective member to be described later has been provided on the target 11, the target 11 is processed by a laser beam process, for example. Therefore, the target 11 represents an object on which the protective member is to be formed and also a workpiece to be processed by a predetermined process. The target 11 is, for example, a disk-shaped wafer or substrate made of a semiconductor such as monocrystalline silicon and has a face side (first surface) 11a and a reverse side (second surface) 11b that are opposite each other and lie generally parallel to each other.

The target 11 has a plurality of rectangular areas demarcated on the face side 11a by a grid of streets, i.e., projected dicing lines, 13 established thereon. Devices 15 such as integrated circuits (ICs), large-scale-integration (LSI) circuits, light-emitting diodes (LEDs), or microelectromechanical systems (MEMS) devices are constructed respectively in the rectangular areas. The target 11 will be divided along the streets 13 into a plurality of device chips that include the devices 15, respectively. The target 11 is not limited to any materials, shapes, structures, and sizes. For example, the target 11 may be a wafer or substrate made of any semiconductors including gallium arsenide (GaAs), silicon carbide (SiC), indium phosphide (InP), and gallium nitride (GaN) other than silicon, sapphire, glass, ceramic, resin, or metal. The devices 15 are not limited to any kinds, quantities, shapes, structures, sizes, and layouts, either.

Surface irregularities are formed on the face side 11a of the target 11. For example, a plurality of electrodes, i.e., connecting electrodes, 17 that protrude from the surfaces of the devices 15 are connected to the devices 15. The electrodes 17 are in the form of spherical bumps, i.e., protrusive electrodes, made of a metal material such as solder, and are connected to electrodes and terminals included in the devices 15. The electrodes 17 are provided as surface irregularities on part of the face side 11a of the target 11. However, the surface irregularities on part of the face side 11a of the target 11 are not limited to the electrodes 17. For example, surface irregularities may be formed on the face side 11a of the target 11 because of the devices 15 themselves and/or the structure of the devices 15. Moreover, structures such as test element groups (TEGs) for testing the devices 15 may be formed on the streets 13 of the target 11. These structures on the streets 13 may also responsible for surface irregularities on the face side 11a of the target 11. The target 11 with the devices 15 and the electrodes 17 formed on the face side 11a thereof will also be referred to as the “target 11.”

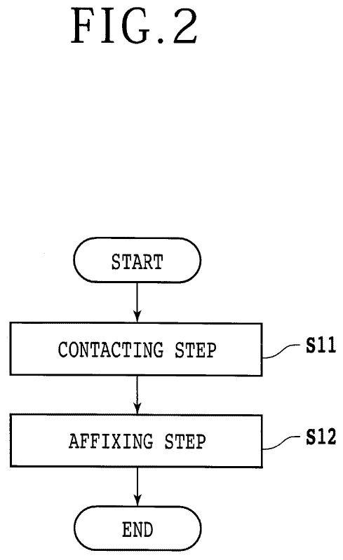

According to the present embodiment, a protective member is fixed to the target 11 with surface irregularities, and thereafter the target 11 is processed. A specific example of the method of fixing a protective member according to the present embodiment will be described below. FIG. 2 is a flowchart of the method of fixing a protective member according to the present embodiment. The method includes contacting step S11 and affixing step S12.

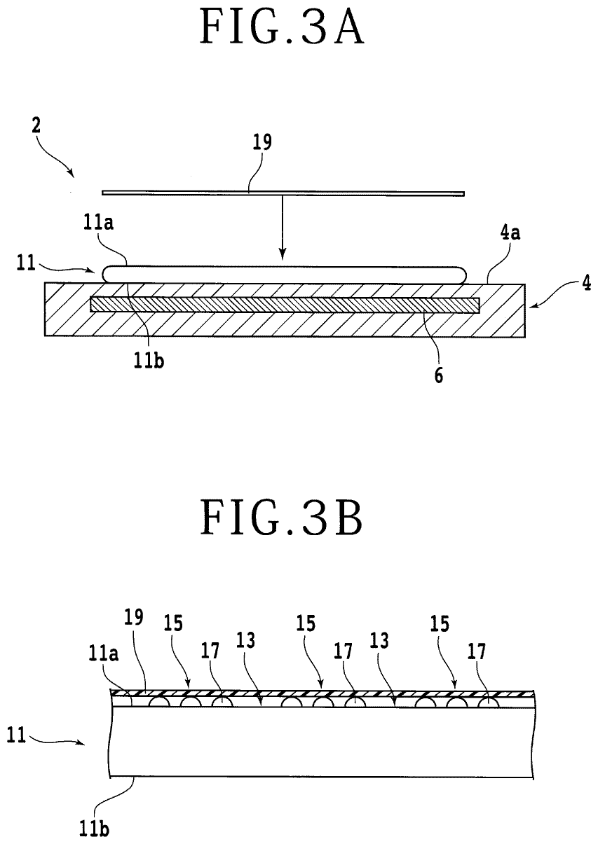

In the method of fixing a protective member according to the present embodiment, first, a water-soluble protective member is prepared, and then brought into contact with the target 11 in contacting step S11. FIG. 3A illustrates, in front elevation, partly in cross section, the target 11 and the protective member, denoted by 19, in contacting step S11.

The protective member 19 includes a sheet-shaped member, i.e., a protective sheet, fixed to the target 11 to protect the target 11. The protective member 19 is made of a material that can be dissolved in water, i.e., is water-soluble. For example, the water-soluble protective member 19 may include a sheet of water-soluble resin such as butenediol vinyl alcohol copolymer (BVOH) or polyvinyl alcohol (PVA). The protective member 19 may be of any shape, size, and thickness, for example, as long as it can protect the target 11. For example, the protective member 19 may be of a circular shape that is generally equal in diameter to the target 11. The protective member 19 may have a thickness in a range from 0.01 to 0.5 mm, for example.

In contacting step S11, a fixing apparatus, i.e., an affixing apparatus, 2 is used to affix the protective member 19 to the target 11. The fixing apparatus 2 includes a holding table 4 for holding the target 11 thereon. The holding table 4 has a flat upper surface lying substantially parallel to a horizontal plane and acting as a holding surface 4a for holding the target 11 thereon.

The holding table 4 has a suction channel, not depicted, defined therein for transmitting suction forces, i.e., a negative pressure, to hold the target 11 under suction on the holding surface 4a. The suction channel has an end exposed on the holding surface 4a and an opposite end fluidly connected to a suction source, not depicted, such as an ejector. While the target 11 is being placed on the holding surface 4a, the suction source is actuated to generate suction forces that are transmitted through the suction cannel and act on the holding surface 4a to hold the target 11 under suction on the holding table 4.

The holding table 4 houses a heat source, i.e., a heater, 6 therein for heating the holding table 4. The heat source 6 may include an electric heater, for example. When the heat source 6 is energized, the heat source 6 is heated to heat the holding table 4 and hence the target 11 held on the holding table 4.

A moving unit, not depicted, and a rotary actuator, not depicted, may be coupled to the holding table 4. The moving unit includes a ball-screw-type moving mechanism, for example, for moving the holding table 4 in horizontal directions, i.e., directions parallel to the holding surface 4a. The rotary actuator includes an electric motor, for example, for rotating the holding table 4 about its central axis that extends vertically, i.e., perpendicularly to the holding surface 4a.

For fixing the protective member 19 to the target 11, first, the target 11 is held on the holding table 4. In a case where the protective member 19 is to be fixed to the face side 11a of the target 11, the target 11 is placed on the holding table 4 such that the face side 11a to be protected faces upwardly and the reverse side 11b faces the holding surface 4a. Then, the protective member 19 is placed on the face side 11a of the target 11. Specifically, the protective member 19 is positioned in covering relation to the devices 15 (see FIGS. 1A and 1B) on the face side 11a of the target 11. The target 11 and the protective member 19 are now kept in contact with each other.

FIG. 3B illustrates, in enlarged fragmentary front elevation, partly in cross section, the target 11 and the protective member 19 after contacting step S11. When the protective member 19 is placed over the face side 11a of the target 11, the protective member 19 is brought into contact with upper tip ends of the electrodes 17. At this time, the protective member 19 tends to enter the gaps between the electrodes 17. However, the protective member 19 is kept in its entirety as a sheet owing to its own rigidity. Therefore, in those areas immediately over the face side 11a of the target 11 where there are no electrodes 17, the face side 11a of the target 11 and the protective member 19 are spaced from each other, leaving clearances therebetween. Specifically, when the protective member 19 is placed over the face side 11a of the target 11, the protective member 19 is only held in contact with portions of the electrodes 17 and is not deformed enough to come into full contact with the electrodes 17 and the face side 11a.

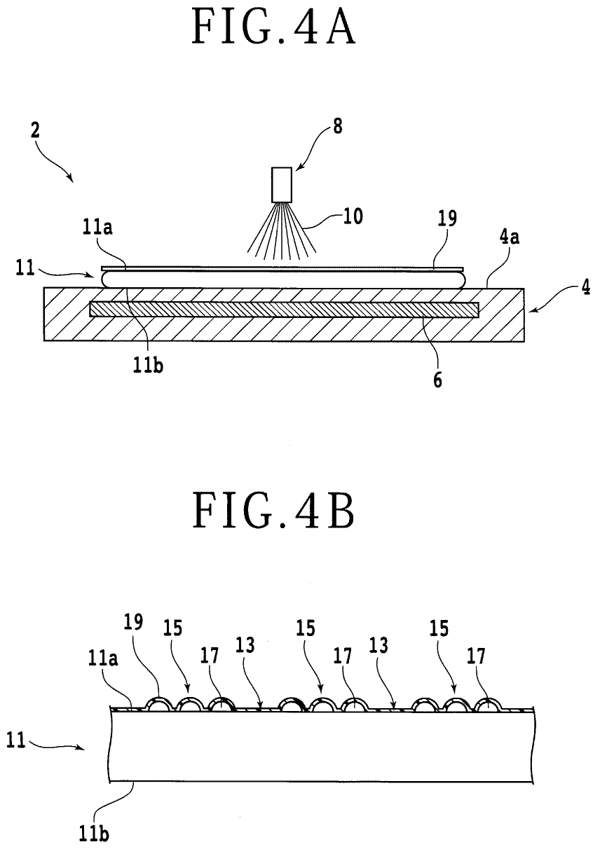

Then, water is supplied to the protective member 19 to affix the protective member 19 to the target 11 in affixing step S12. FIG. 4A illustrates, in front elevation, partly in cross section, the target 11 and the protective member 19 in affixing step S12.

As illustrated in FIG. 4A, the fixing apparatus 2 includes a water supply unit 8 for supplying water 10. Specifically, the water supply unit 8 supplies a mist of water 10 to the protective member 19. For example, the water supply unit 8 is disposed above the holding surface 4a of the holding table 4 and ejects the mist of water 10 toward the protective member 19 held in contact with the target 11 that is held on the holding table 4.

The water supply unit 8 may be of any type and structure as long as it can supply the mist of water 10. For example, the water supply unit 8 may include an atomizer including a spray nozzle for ejecting a mist of water under pressure from an ejection port or an atomizer ejecting a mist of water due to the Venturi effect.

In addition, the water supply unit 8 may include an ultrasonic nozzle for applying ultrasonic vibrations, i.e., vibrations at a frequency in the ultrasonic range, to atomize water and eject it as a mist of water. For example, the ultrasonic nozzle includes a reservoir for temporarily keeping water and an ultrasonic vibrator for applying ultrasonic vibrations to the water kept in the reservoir. The ultrasonic vibrator includes a piezoelectric member made of a piezoelectric ceramic material such as barium titanate, lead zirconate titanate, or lithium tantalate, and electrodes connected to the piezoelectric member for applying a high-frequency voltage across the piezoelectric member. When the ultrasonic vibrator is energized, it applies ultrasonic vibrations at a frequency ranging from 20 to 60 kHz, for example, to the water kept in the reservoir. When the water to which the ultrasonic vibrations are applied is ejected from the ejection port of the ultrasonic nozzle, the water is atomized into a mist of water. The ultrasonic vibrator may apply ultrasonic vibrations directly to the water or may apply ultrasonic vibrations via another member such as a vibratory plate to the water.

The water supply unit 8 is arranged to supply the water 10 to the protective member 19 in its entirety. For example, a moving unit, not depicted, is coupled to the water supply unit 8 for moving the water supply unit 8 in horizontal directions parallel to the holding surface 4a of the holding table 4. When the moving unit moves the water supply unit 8 horizontally relatively to the holding table 4, the water supply unit 8 can supply a mist of water 10 to any desired areas of the protective member 19 that include the entire area thereof. However, the water supply unit 8 may be arranged to supply the water 10 to the protective member 19 in its entirety while the holding table 4 and the water supply unit 8 are being held at rest.

In affixing step S12, while the target 11 and the protective member 19 are being kept in contact with each other, the water supply unit 8 ejects the mist of water 10 to the protective member 19 in its entirely as the holding table 4 and the water supply unit 8 are moved relatively to each other if necessary. In this manner, the protective member 19 is supplied in its entirety with the mist of water 10. The water 10 supplied to the protective member 19 pervades the protective member 19 in its entirety. Since the protective member 19 is water-soluble as described above, part of the protective member 19 pervaded by the water 10 is dissolved by the water 10 to accelerate deformation of the protective member 19, making the protective member 19 easier to be affixed to the target 11. Inasmuch as the mist of water 10 has been supplied to the protective member 19 and hence the amount of water 10 supplied to the protective member 19 is relatively small, the protective member 19 is not completely dissolved and thus remains shaped as a sheet (semi-dissolved state).

FIG. 4B illustrates, in enlarged fragmentary front elevation, partly in cross section, the target 11 and the protective member 19 after affixing step S12. When the mist of water 10 is supplied to the protective member 19, the protective member 19 is partly deformed, and portions of the protective member 19 that are not kept in contact with and not supported on the electrodes 17 enter the gaps between the electrodes 17. As described above, as the protective member 19 is partly dissolved, it is easily affixed to the target 11. As a result, the protective member 19 is deformed enough to come into full contact with the electrodes 17 and the face side 11a, so that the protective member 19 is brought in its entirety into intimate contact with the target 11. The protective member 19 is thus affixed and secured to the target 11 along the surface irregularities thereof while keeping its own generally uniform thickness.

In affixing step S12, the protective member 19 should preferably be affixed to the target 11 while the protective member 19 is being heated. Specifically, before, after, or while the water 10 is supplied to the protective member 19, the heat source 6 is energized to heat the holding table 4. Therefore, the heat generated by the heat source 6 is transmitted through the holding table 4 to the target 11 and the protective member 19, thereby heating the target 11 and the protective member 19. For example, the target 11 and the protective member 19 are heated to a temperature ranging from 50° C. to less than 100° C., or preferably ranging from 60° C. to 80° C. In order to prevent the water 10 from being evaporated, the target 11 and the protective member 19 should preferably be heated to a temperature less than 100° C. The heating of the protective member 19 accelerates the affixing of the protective member 19 to the target 11, resulting in a reduced period of time required to secure the protective member 19 to the target 11.

A change in the atmospheric pressure may be used in affixing the protective member 19 to the target 11. Specifically, in contacting step S11 (see FIG. 3A), the target 11 and the protective member 19 are brought into contact with each other in a decompressed environment, i.e., under a pressure lower than the atmospheric pressure. For example, a decompression chamber is prepared, and while the decompression chamber is being evacuated, the protective member 19 is brought into contact with the target 11 in the decompression chamber. In this manner, gas, i.e., air, is less likely to enter between the target 11 and the protective member 19, which are thus brought into intimate contact with each other without being obstructed by air bubbles. The decompression chamber is evacuated to a pressure, i.e., an absolute pressure, ranging from 10 to 100 Pa, for example.

After the target 11 and the protective member 19 have contacted each other, the decompression chamber is vented to the atmosphere, so that air, i.e., the atmosphere, is introduced into the decompression chamber. The pressure in the decompression chamber rises, causing the atmospheric pressure to act on the protective member 19. As a result, the protective member 19 is deformed under the atmospheric pressure along the surface irregularities of the target 11 and pressed into intimate contact with the target 11. In this manner, the protective member 19 is affixed to the target 11. The atmospheric pressure may act on the protective member 19 before, after, or while the water 10 (see FIG. 4A) is supplied to the protective member 19.

After the protective member 19 has been affixed to the target 11, a drying treatment may be carried out to accelerate the drying of the target 11 and the protective member 19 in a drying step. The drying step may be performed by energizing the heat source 6 to heat the target 11 and the protective member 19 or applying hot air generated by heating air to the target 11 and the protective member 19.

According to the present embodiment, the protective member 19 is fixed to the face side 11a of the target 11 that has surface irregularities. In a case where the reverse side 11b of the target 11 has surface irregularities, the protective member 19 may be fixed to the reverse side 11b of the target 11 in the same manner as described above. The surface to be protected of the target 11 to which the protective member 19 is to be fixed is determined depending on the details of a step in which the target 11 is to be processed subsequently.

As described above, after the protective member 19 has been brought into contact with the water-soluble target 11, the protective member 19 is affixed to the target 11 along its surface irregularities by being supplied with the mist of water 10. In this fashion, thickness variations of the protective member 19 fixed to the target 11 are reduced.

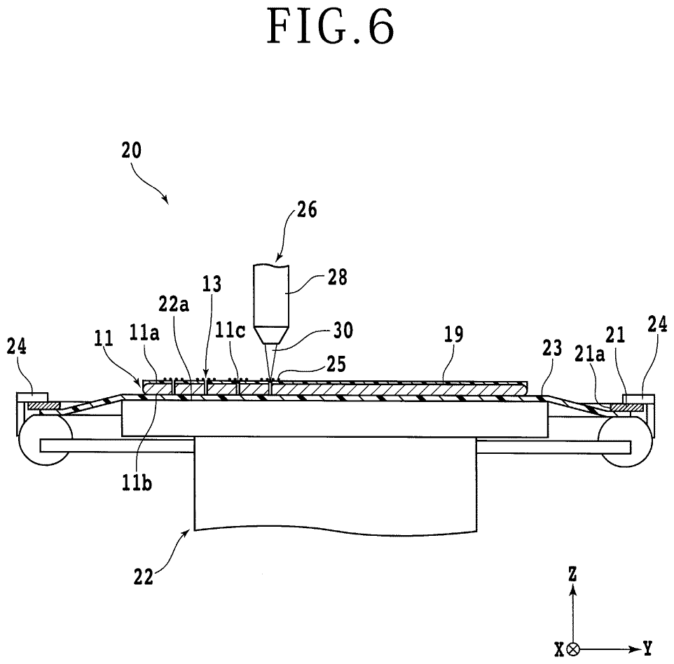

After the protective member 19 has been fixed to the target 11, the target 11 is processed according to a predetermined step (processing step). A laser beam step that is to be performed on the target 11 by a laser processing apparatus 20 (see FIG. 6) will be described below as an example of the predetermined process.

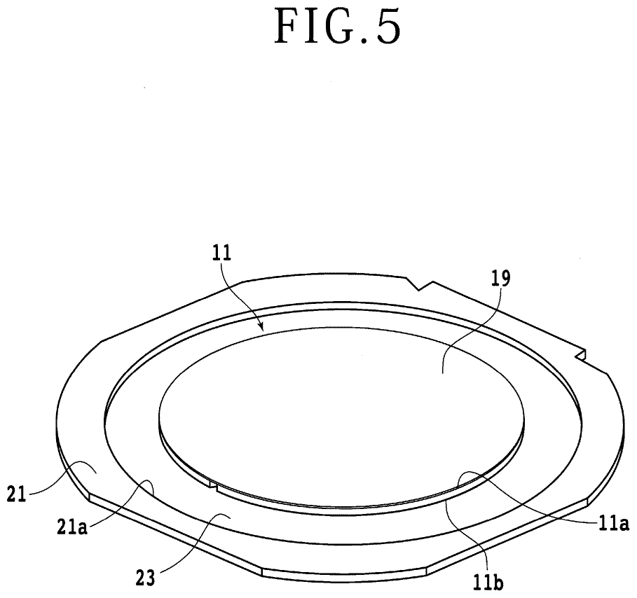

FIG. 5 illustrates, in perspective, the target 11 with the protective member 19 fixed thereto. For processing the target 11 according to the laser beam process, the target 11 is supported on an annular frame 21 for the ease with which to handle, i.e., to deliver and hold, the target 11. The frame 21 is made of a metal material such as stainless steel (SUS) and has a circular opening 21a defined centrally in the frame 21 and extending thicknesswise through the frame 21. The opening 21a is larger than the target 11 in diameter.

A circular sheet 23 is secured to the target 11 and the frame 21. The sheet 23 includes a circular film-shaped base and a tape disposed on the base and including an adhesive layer, i.e., a glue layer. The base is made of resin such as polyolefin, polyvinyl chloride, or polyethylene terephthalate, for example, whereas the adhesive layer is made of an epoxy-based, acryl-based, or rubber-based adhesive or an ultraviolet-curable resin. Alternatively, the sheet 23 may be a thermocompression bonding sheet that is free of the adhesive layer and can be secured to the target 11 and the frame 21 by way of thermocompression bonding.

With the target 11 disposed within the opening 21a in the frame 21, the sheet 23 has its central area affixed to the reverse side 11b of the target 11 and its outer circumferential area affixed to the frame 21. In this manner, the target 11 is supported on the frame 21 by the sheet 23. The target 11 supported on the frame 21 with the protective member 19 fixed thereto is delivered to the laser processing apparatus 20 (see FIG. 6).

FIG. 6 illustrates the laser processing apparatus 20, in front elevation, partly in cross section. As illustrated in FIG. 6, the laser processing apparatus 20 is illustrated in reference to a three-dimensional XYZ coordinate system having an X-axis indicated by an arrow X, a Y-axis indicated by an arrow Y, and a Z-axis indicated by an arrow Z. The X-axis represents first horizontal directions or processing feed directions and the Y-axis represents second horizontal directions or indexing feed directions, the X-axis and the Y-axis being perpendicular to each other. The Z-axis represents upward and downward directions, heightwise directions, or vertical directions and is perpendicular to the X-axis and the Y-axis.

The laser processing apparatus 20 includes a holding table, i.e., a chuck table, 22 for holding the target 11 thereon. The holding table 22 has a flat upper surface lying generally parallel to a horizontal plane defined as an XY plane in the three-dimensional XYZ coordinate system. The upper surface of the holding table 22 acts as a holding surface 22a for holding the target 11 thereon. The holding surface 22a is fluidly connected to a suction source, not depicted, such as an ejector via a fluid channel, not depicted, defined in the holding table 22 and a valve, not depicted.

A moving unit, not depicted, and a rotary actuator, not depicted, are coupled to the holding table 22. The moving unit includes a ball-screw-type moving mechanism, for example, for moving the holding table 22 in the horizontal directions along the X-axis and the Y-axis. The rotary actuator includes an electric motor, for example, for rotating the holding table 22 about its central axis that extends generally parallel to the Z-axis. A plurality of clamps 24 are disposed at spaced intervals around the holding table 22 for gripping and securing the frame 21 in position.

The laser processing apparatus 20 also includes a laser beam applying unit 26 for applying a laser beam. The laser beam applying unit 26 includes a laser oscillator, not depicted, that generates such a laser as a yttrium aluminum garnet (YAG) laser, a yttriumvanadate (YVO₄) laser, or a yttrium lithium fluoride (YLF) laser and a laser processing head 28 disposed above the holding table 22. The laser processing head 28 incorporates therein an optical system for guiding a pulse-oscillated laser beam 30 emitted from the laser oscillator to the target 11 on the holding table 22. The optical system includes an optical device, not depicted, such as a condensing lens for converging the laser beam 30 into a focused spot at a predetermined position. The laser processing head 28 applies the laser beam 30 to the target 11 to process the target 11 with the laser beam 30.

For performing the laser beam step on the target 11, the target 11 is held on the holding table 22. Specifically, the target 11 is placed on the holding table 22 such that the face side 11a, i.e., the protective member 19, faces upwardly and the reverse side 11b, i.e., the sheet 23, faces the holding surface 22a. The frame 21 is secured in position by the clamps 24. Then, the suction source is actuated to generate suction forces, i.e., a negative pressure, that are transmitted through the suction channel and act on holding surface 22a to hold the target 11 via the sheet 23 under suction on the holding surface 22a.

Then, the holding table 22 is turned about its central axis to align a group of parallel streets 13 on the target 11 with the X-axis. The holding table 22 is also adjusted in position along the Y-axis until an area irradiated with the laser beam 30 from the laser processing head 28 is positioned on an extension of one of the streets 13 along the X-axis. Moreover, the position of the laser processing head 28 and the layout of the optical system are adjusted to position the focused spot of the laser beam 30 at the same height as the target 11.

Then, while the laser processing head 28 is applying the laser beam 30, the holding table 22 is moved along the X-axis. The holding table 22 and the laser beam 30 are thus moved relatively to each other along the X-axis at a predetermined speed, i.e., a predetermined processing feed speed, causing the laser beam 30 to be applied via the protective member 19 to the target 11 along the street 13. As a result, the target 11 is processed along the street 13 by the laser beam 30.

Conditions under which the laser beam 30 is applied to the target 11 are established depending on the details of the laser beam step performed on the target 11. For example, in a case where the laser beam step performed on the target 11 is an ablation process, the laser beam 30 has a wavelength selected such that at least part of the laser beam 30 will be absorbed by the target 11. In other words, the laser beam 30 is absorbable by the target 11. Other conditions under which the laser beam 30 is applied to the target 11 are established to perform the ablation step appropriately on the target 11. For example, providing the target 11 is a monocrystalline silicon wafer, the laser beam 30 may be applied to the target 11 under the following conditions:
Wavelength: 355 nm
Average output power: 2 W
Repetitive frequency: 200 kHz
Processing feed speed: 400 mm/s

When the laser beam 30 is applied to the target 11 along the street 13, the region of the target 11 that is irradiated with the laser beam 30 is removed by the ablation process. As a consequence, a processed groove 11c extending through the target 11 from the face side 11a to the reverse side 11b is formed in the target 11 along the street 13. The target 11 is thus divided along the street 13. At this time, the laser beam 30 may be transmitted through the protective member 19 and applied to the target 11, leaving the protective member 19 unremoved, or may be applied to both the protective member 19 and the target 11, removing their irradiated regions along the street 13.

When the target 11 is processed by the laser beam process, swarf 25 such as melted mass or debris is produced from the target 11 in its region irradiated with the laser beam 30. At this time, the protective member 19 on the face side 11a of the target 11 blocks the swarf 25, and it will not be attached to the face side 11a of the target 11. In this manner, the target 11, the devices 15, and the electrodes 17 (see FIG. 1A, for example) are prevented from being contaminated by the swarf 25.

The above laser beam processing is repeated to form processed grooves 11c in the target 11 along other streets 13 parallel to the street 13 along which the processed groove 11c has already been formed in the target 11. When processed grooves 11c have been formed in the target 11 along all the streets 13 established thereon, the target 11 is divided along the processed grooves 11c into a plurality of device chips that include the respective devices 15 (see FIG. 1A, for example).

In the ablation process, the laser beam 30 may be applied to the target 11 repeatedly a plurality of times along each of the streets 13 to form processed grooves 11c in the target 11 respectively along the streets 13. In this case, the processed grooves 11c extending from the face side 11a to the reverse side 11b may be formed in the target 11 by the laser beam 30 whose average output power is reduced in each pass. The reduced average output power of the laser beam 30 is effective to minimize adverse thermal effects on the target 11, the devices 15, and the electrodes 17 (see FIG. 1A, for example), making them less susceptible to unwanted processing defects.

The laser beam processing to be performed on the target 11 is not limited to the details described above. For example, the laser beam processing may be carried out to form processed grooves whose depth is smaller than the thickness of the target 11 in the face side 11a of the target 11 along the streets 13. In this case, after the laser beam process, external forces are applied to the target 11 to rupture the target 11 along the processed grooves that act as division initiating points until finally the target 11 is fully divided along the streets 13. Alternatively, an annular cutting blade may be forced to cut into the bottoms of the processed grooves along the streets 13 while it is being rotated about its central axis, thereby dividing the target 11 along the streets 13.

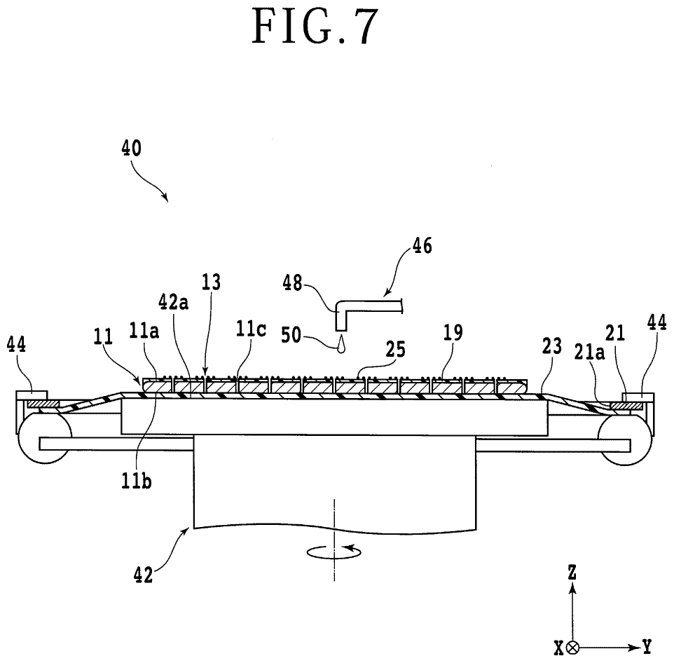

When the laser beam processing on the target 11 is completed, the protective member 19 is removed from the target 11 in a protective member removing step. FIG. 7 illustrates, in front elevation, partly in cross section, a cleaning apparatus 40 for removing the protective member 19 from the target 11. For example, in the protective member removing step, the cleaning apparatus 40 cleans the protective member 19 and the target 11 to remove the protective member 19 from the target 11. The cleaning apparatus 40 may be incorporated in the laser processing apparatus 20 (see FIG. 6) or may be provided independently of the laser processing apparatus 20.

The cleaning apparatus 40 includes a spinner table 42 for holding and rotating the target 11. The spinner table 42 has a flat upper surface lying generally parallel to an XY or horizontal plane. The upper surface of the spinner table 42 acts as a holding surface 42a for holding the target 11 thereon. The holding surface 42a is fluidly connected to a suction source, not depicted, such as an ejector via a fluid channel, not depicted, defined in the spinner table 42 and a valve, not depicted.

A rotary actuator, not depicted, such as an electric motor, for example, for rotating the spinner table 42 about its central axis that extends generally parallel to the Z-axis is coupled to the spinner table 42. A plurality of clamps 44 are disposed at spaced intervals around the spinner table 42 for gripping and securing the frame 21 in position.

The cleaning apparatus 40 also includes a cleaning liquid supply unit 46 for supplying a cleaning liquid. The cleaning liquid supply unit 46 includes a nozzle 48 for supplying a cleaning liquid 50 to the target 11 held on the spinner table 42. A moving mechanism, not depicted, for moving the nozzle 48 along an XY or horizontal plane is coupled to the nozzle 48. When the moving mechanism is actuated, it can position the nozzle 48 in a position over the holding surface 42a of the spinner table 42. The cleaning liquid 50 may be made of any material capable of removing the protective member 19. For example, the cleaning liquid 50 may include a liquid such as pure water or a mixed fluid containing a liquid such as pure water and gas such as air.

The target 11 that has been processed by the laser beam processing is delivered to the cleaning apparatus 40 and then held on the spinner table 42. Specifically, the target 11 is placed on the spinner table 42 such that the face side 11a, i.e., the protective member 19 side, faces upwardly and the reverse side 11b, i.e., the sheet 23 side, faces the holding surface 42a. The frame 21 is secured in position by the clamps 44. Then, the suction source is actuated to generate suction forces, i.e., a negative pressure, that are transmitted through the suction channel and act on holding surface 42a to hold the target 11 via the sheet 23 under suction on the holding surface 42a.

Then, the nozzle 48 is placed in a position over the target 11 in vertical alignment with the central axis of the spinner table 42. While the spinner table 42 is being rotated about its central axis, the nozzle 48 supplies the cleaning liquid 50 to the target 11 on the spinner table 42. The cleaning liquid 50 is now supplied to the central region of the target 11 and then forced to flow radially outwardly toward the outer circumferential edge of the target 11 under centrifugal forces generated by the rotating target 11. As a result, the cleaning liquid 50 spreads all over the protective member 19, removing the protective member 19 together with the swarf 25.

Since the protective member 19 is water-soluble, the cleaning liquid 50 supplied to the protective member 19 dissolves the protective member 19, so that the protective member 19 can easily be removed from the target 11. The amount of cleaning liquid 50 that is supplied and the time during which the cleaning liquid 50 is supplied are appropriately selected to dissolve and clean away the protective member 19 from the target 11.

As described above, in the method of fixing a protective member according to the present embodiment, after the protective member 19 has been brought into contact with the water-soluble target 11, the mist of water 10 is supplied to the protective member 19. The protective member 19 is affixed to the target 11 along its surface irregularities. In this fashion, thickness variations of the protective member 19 due to the surface irregularities of the target 11 are reduced.

According to the present embodiment, the protective member 19 is supplied with the mist of water 10 (see FIG. 4A). However, providing the amount of water 10 to be supplied can strictly be controlled to supply a small amount of water 10 to the protective member 19 in a manner to prevent the protective member 19 from being fully dissolved by the water 10, the water 10 may not necessarily be supplied as a mist.

According to the present embodiment, the target 11 includes a workpiece to be processed by the laser beam process. However, the target 11 may be an object other than such a workpiece. For example, the protective member 19 may be fixed to a processing tool for processing a workpiece. The protective member 19 that is fixed to such a processing tool is effective to protect the processing tool from damage such as scratches and cracks and foreign matter.

Examples of processing tool may include a cutting blade for cutting a workpiece, a grinding wheel for grinding a workpiece, and a polishing pad for polishing a workpiece. The cutting blade includes a disk-shaped base and an annular cutting edge, i.e., a processing part, formed along an outer circumferential portion of the base. The grinding wheel includes an annular base and a plurality of grindstones, i.e., a processing part, fixed to the base. The polishing pad includes a disk-shaped base and a disk-shaped polishing layer, i.e., a processing part, fixed to the base.

The protective member 19 is fixed to such a processing tool in covering relation to the base and the processing part, thereby protecting the processing tool. The processing tool is stored and delivered with the protective member 19 fixed thereto. When the processing tool is to be used, water is applied to the protective member 19 immediately prior to the use of the processing tool, thereby easily removing the protective member 19 from the processing tool. The protective member 19 may be fixed to the processing tool in covering relation to the entire processing tool or may be fixed to the processing tool in covering relation to only a portion of the processing tool that needs to be protected. Furthermore, the protective member 19 may be fixed to an inspection equipment such as an ultrasonic probe, for example.

The structural and methodical details of the present embodiment may appropriately be changed or modified without departing from the scope of the invention.

### Second Embodiment

According to the first embodiment, after the protective member 19 has been brought into contact with the target 11, the mist of water 10 is supplied to the protective member 19 to affix the protective member 19 to the target 11 (see FIGS. 3A and 4A). However, the protective member 19 may be fixed to the target 11 according to other sequences.

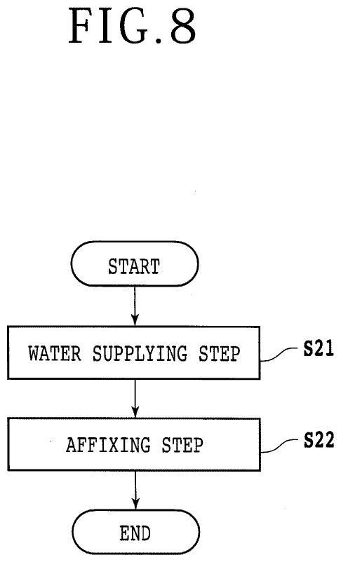

FIG. 8 is a flowchart of a method of fixing a protective member according to a second embodiment of the present invention. According to the second embodiment, the water 10 is supplied to the target 11 or the protective member 19 (water supplying step S21), and thereafter the protective member 19 is affixed to the target 11 by bringing the protective member 19 and the target 11 into contact with each other (affixing step S22). The method of fixing a protective member according to the second embodiment will be described by way of specific example below. Some details of the method of fixing a protective member according to the second embodiment are identical to the corresponding details of the method of fixing a protective member according to the first embodiment. Therefore, those identical features will be omitted from description below, and reference should be made to the first embodiment with regard to the omitted features according to the second embodiment.

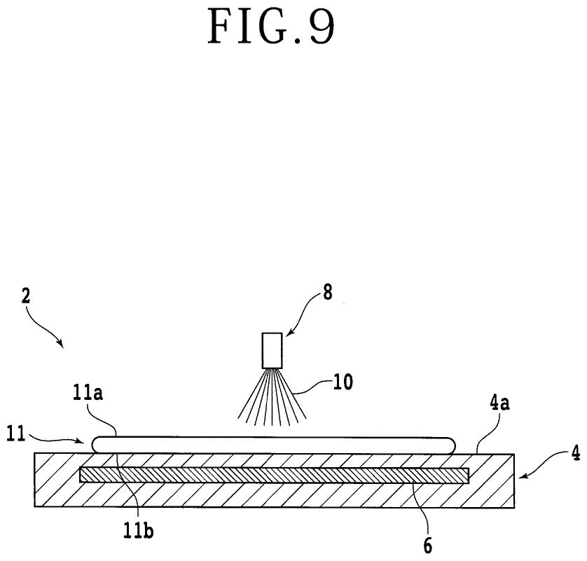

FIG. 9 illustrates, in front elevation, partly in cross section, the target 11 and the protective member 19 in water supplying step S22. In water supplying step S22, the target 11 or the protective member 19 is supplied with the water 10 to apply the water 10 to the target 11 or the protective member 19. A step of supplying a mist of water 10 to the target 11 to supply the water 10 to the surface to be protected of the target 11 to which the protective member 19 is to be fixed will be described by way of example below.

In water supplying step S21, first, the target 11 is held on the holding table 4 of the fixing apparatus 2. In a case where the protective member 19 is to be fixed to the face side 11a of the target 11, the target 11 is placed on the holding table 4 such that the face side 11a to be protected faces upwardly and the reverse side 11b faces the holding surface 4a. Then, the water supply unit 8 is positioned above the target 11. Thereafter, while the holding table 4 and the water supply unit 8 are being moved relatively to each other if necessary, the water supply unit 8 ejects the mist of water 10 to the face side 11a of the target 11. The face side 11a of the target 11 in its entirety is thus supplied with the water 10, so that a small amount of water 10 is applied to the face side 11a of the target 11. The amount of water 10 to be supplied is adjusted such that when the protective member 19 is brought into contact with the face side 11a of the target 11 in affixing step S22 to be described below, the protective member 19 will not be dissolved in its entirety by the water 10 applied to the face side 11a of the target 11.

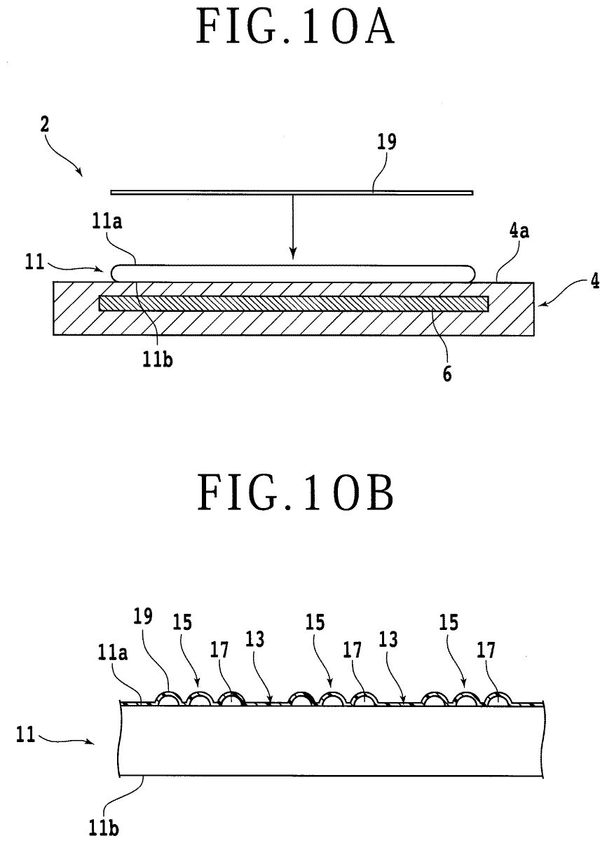

FIG. 10A illustrates, in front elevation, partly in cross section, the target 11 and the protective member 19 in affixing step S22. In affixing step S22, the target 11 and the protective member 19 are brought into contact with each other to affix the protective member 19 to the target 11. Specifically, the protective member 19 is prepared, and then brought into contact with the surface of the target 11 to which the water 10 has been applied, i.e., the face side 11a thereof. At this time, the protective member 19 is positioned in covering relation to the devices 15 (see FIGS. 1A and 1B) on the face side 11a of the target 11.

When the protective member 19 is placed on the face side 11a of the target 11, the water 10 applied to the face side 11a of the target 11 contacts the protective member 19. The water 10 pervades the protective member 19, dissolving part of the protective member 19 and accelerating deformation of the protective member 19, making the protective member 19 easier to be affixed to the target 11. Inasmuch as the mist of water 10 has been supplied to the target 11 and hence the amount of water 10 applied to the face side 11a of the target 11 is relatively small, the protective member 19 is not completely dissolved and thus remains shaped as a sheet (semi-dissolved state).

In affixing step S22, the entire protective member 19 may be semi-dissolved state, or only part of the surface of the protective member 19 that is held in contact with the target 11, i.e., the lower surface of the protective member 19 in FIG. 10A, may be semi-dissolved state. The scope of the protective member 19 that is to be semi-dissolved state may be adjusted by the amount of water 10 to be applied to the target 11.

FIG. 10B illustrates, in front elevation, partly in cross section, the target 11 and the protective member 19 after affixing step S22. When the water 10 contacts the protective member 19, the water 10 accelerates deformation of the protective member 19, deforming the protective member 19 along the face side 11a of the target 11 and the electrodes 17 thereon. As part of the protective member 19 is dissolved, the protective member 19 becomes easier to be fixed to the target 11. Therefore, the protective member 19 in its entirety is held in intimate contact with the target 11. In this manner, the protective member 19 is affixed to the target 11 along the surface irregularities thereof and fixed to the target 11.

In water supplying step S21, the mist of water 10 may be supplied to the protective member 19 in place of the target 11. Specifically, before the protective member 19 is brought into contact with the target 11, the mist of water 10 is supplied to the protective member 19 to let itself pervade the protective member 19. The protective member 19 is thus semi-dissolved state. In this case, the entire protective member 19 may be semi-dissolved state by causing the water 10 to pervade the protective member 19 in its entirety, or only part of the surface of the protective member 19 that is held in contact with the target 11, i.e., the lower surface of the protective member 19 in FIG. 10A, may be semi-dissolved state by causing the water 10 to pervade only the part of the protective member 19. For example, after the mist of water 10 has been supplied to the lower surface of the protective member 19, the protective member 19 is brought into contact with the target 11. Alternatively, after the mist of water 10 has been supplied to the upper surface of the protective member 19, the protective member 19 may be turned upside down and brought into contact with the target 11.

Thereafter, the target 11 and the protective member 19 are caused to contact each other. The partly dissolved protective member 19 is thus deformed along the face side 11a of the target 11 and the electrodes 17, so that the protective member 19 is affixed to the target 11 in affixing step S22.

As described above, the protective member 19 can be affixed to the target 11 by being brought into contact with the target 11 after the water 10 has been supplied to the target 11 or the protective member 19. In affixing step S22, the protective member 19 may be brought into contact with the target 11 while the protective member 19 is being heated by the heat source 6. After the target 11 and the protective member 19 have been brought into contact with each other in a decompressed environment, the atmospheric pressure may be applied to the protective member 19 to bring the protective member 19 into intimate contact with the target 11.

According to the present embodiment, the water 10 may not necessarily be supplied as a mist. The target 11 may be an object other than such a workpiece. The protective member 19 may be fixed to a processing tool or an inspection equipment in part or its entirety.

The structural and methodical details of the present embodiment may appropriately be changed or modified without departing from the scope of the invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of fixing a water-soluble protective member to a target, the method comprising:
a contacting step of bringing the target and the protective member into contact with each other; and
after the contacting step, an affixing step of affixing the protective member to the target by supplying water to the protective member.

2. A method of fixing a water-soluble protective member to a target, the method comprising:
a water supplying step of supplying water to the target; and
after the water supplying step, an affixing step of affixing the protective member to the target by bringing a surface of the target to which the water has been applied and the protective member into contact with each other.

3. A method of fixing a water-soluble protective member to a target, the method comprising:
a water supplying step of supplying water to the protective member; and
after the water supplying step, an affixing step of affixing the protective member to the target by bringing the target and the protective member into contact with each other.

4. The method of fixing a water-soluble protective member according to claim 1, wherein the water is supplied as a mist of water to the protective member.

5. The method of fixing a water-soluble protective member according to claim 1, wherein the protective member is affixed to the target while the protective member is being heated.

6. The method of fixing a water-soluble protective member according to claim 1, wherein the target and the protective member are brought into contact with each other in a decompressed environment.

7. The method of fixing a water-soluble protective member according to claim 2, wherein the water is supplied as a mist of water to the target.

8. The method of fixing a water-soluble protective member according to claim 2, wherein the protective member is affixed to the target while the protective member is being heated.

9. The method of fixing a water-soluble protective member according to claim 2, wherein the target and the protective member are brought into contact with each other in a decompressed environment.

10. The method of fixing a water-soluble protective member according to claim 3, wherein the water is supplied as a mist of water to the protective member.

11. The method of fixing a water-soluble protective member according to claim 3, wherein the protective member is affixed to the target while the protective member is being heated.

12. The method of fixing a water-soluble protective member according to claim 3, wherein the target and the protective member are brought into contact with each other in a decompressed environment.
